(19) United States
(12) Patent Application Publication
(10) Pub. No.: US 2014/0076516 A1
(43) Pub. Date: Mar. 20, 2014

(54) HEAT TREATMENT APPARATUS AND HEAT TREATMENT METHOD

(71) Applicant: Panasonic Corporation, Osaka (JP)

(72) Inventors: MITSUO SAITOH, Osaka (JP); TOMOHIRO OKUMURA, Osaka (JP)

(73) Assignee: Panasonic Corporation, Osaka (JP)

(21) Appl. No.: 14/025,830

(22) Filed: Sep. 13, 2013

(30) Foreign Application Priority Data
Sep. 18, 2012 (JP) 2012-204063
Aug. 20, 2013 (JP) 2013-170095

(51) Int. Cl. H01L 21/67

(52) U.S. Cl. CPC H01L 21/67115
USPC 165/64; 165/61; 432/18

(57) ABSTRACT

In a heat treatment apparatus, crystallization can be performed at a relatively low temperature, thereby limiting size of a crystal grain diameter even when a long period of time such as several dozen hours is taken. The heat treatment apparatus is provided with a first temperature mechanism having a heater heating a base material on the back side of the base material as well as a mechanism cooling the front surface of the base material by using coolant on the front surface side of the base material, a second temperature mechanism heating the front surface side of the base material by using any of atmospheric plasma unit, laser and a flash lamp, a third temperature mechanism having a heater heating the base material from the front surface side of the base material, in which the first to third temperature mechanisms are sequentially arranged in this order, and a movement mechanism relatively moves the first to third temperature mechanisms.

### CROSS REFERENCE TO RELATED APPLICATIONS

This application is entitled and claims the benefit of foreign priority of Japanese Patent Application No. 2012-204063, filed on Sep. 18, 2012, and Japanese Patent Application No. 2013-170095, filed on Aug. 20, 2013, the contents of both of which are incorporated herein by reference.

### BACKGROUND OF THE INVENTION

1. Field of the Invention

The present invention relates to a heat treatment apparatus and a heat treatment method.

2. Background Art

In recent years, a technology of heating a thin film deposited on a base material by using a technique such as a CVD method at high speed and at high temperature without causing heat damage to the base material by using laser or RTA (Rapid Thermal Anneal) has been developed in the fields of liquid crystal, solar cells and so on. The main purposes thereof are to improve mobility or lifetime of carriers included in a semiconductor, to improve characteristics of a product and to maintain high productivity as short-time processing by performing phase transition of the thin film to a crystalline phase and so on.

For example, in a case of a solar cell field, inventions relating to thin-film solar cells have been made for the purpose of reducing the thickness of a silicon substrate as thin as possible for reducing a material cost of silicon occupying approximately 30% of manufacturing costs.

In these thin-film solar cells, it is generally known that the thin-film solar cell in which a desired semiconductor layer is formed by sequentially stacking deposition layers chiefly made of silicon by using a CVD method, a sputtering method, a deposition method and so on can be formed to be extremely thin with respective film thickness of several nm to several dozen μm (see Basics and applications in thin-film solar cells/KONAGAI, Makoto/Ohmsha, Ltd. (Non-Patent Document 1)).

However, particularly in the thin-film solar cells using silicon (Si), silicon germanium (SiGe), germanium (Ge), silicon carbide (SiC) and so on, it is difficult to form a monocrystal layer or a polycrystalline layer at low costs due to technical difficulty caused by the thin-film construction method. This is because, in general, a carrier diffusion length in which carriers can move in the film is extremely small as an amorphous phase or a microcrystal phase including extremely small crystal grains having approximately 10 nm in grain diameter is formed.

Under such background, a technique attracts attention in recent years, in which, after a silicon amorphous film is deposited by the thin-film construction method, heat treatment called a SPC method (solid phase crystallization) at a low temperature of approximately 600° C. for a relatively long period of time for 10 to several dozen hours is performed to form a silicon crystalline layer in which the crystal grain diameter is expanded to the Φ2500 nm level. It is known that the carrier diffusion layer can be improved and relatively high power generation efficiency can be realized by the above technique (see The University of New South Wales, Photovoltaics Center of Excellence, Annual report (2009) (Non-Patent Document 2)).

On the other hand, the technique of crystallizing the silicon thin film at low costs while applying the silicon thin film for display applications typified by an LCD and an OLED has been developed for almost the same purpose as the above solar-cell applications. An example of the technique will be described below as a related-art example in the content described in Japanese Patent No. 4796056 (Patent Document 1).

In order to crystallize a semiconductor layer (aSi layer) formed on a glass base material or in order to activate a dopant, after depositing the semiconductor layer, a thermal profile in which relatively gentle temperature up and temperature down are combined disclosed in Patent Document 1 (FIG. 16) is realized at a relatively low temperature of approximately 500° C. to 850° C. by a method of controlling relatively gentle temperature up and temperature down (SPC method) using a heat treatment apparatus (a structure in which plural heating furnaces and cooling furnaces are connected) disclosed in Patent Document 1 (FIG. 1). The technique capable of performing heat treatment while suppressing rapid temperature change and local temperature difference as well as avoiding deformation and damage of the semiconductor layer on the front surface of the glass base material according to the above processes is proposed.

The present inventors has also confirmed that the silicon thin film deposited on the glass base material is crystallized while reducing damage and deformation in the base material and the semiconductor layer by the SPC method using the same heat treatment apparatus and the method by referring to Patent Document 1 and Non-Patent Document 2.

### SUMMARY OF THE INVENTION

However, as crystallization is performed at the relatively low temperature of approximately 500° C. to 850° C. in the above-described related-art heat treatment apparatus and the method thereof, the size of the crystal grain diameter remains approximately Φ2500 nm even when a long period of time for approximately 30 hours are taken. There is a problem that it is extremely difficult to increase the crystal grain diameter as heat treatment at the high temperature is difficult, particularly for realizing crystallization without causing damage and deformation of the semiconductor layer on the inexpensive glass base material.

The present invention has been made for solving the above problems in the related art, and an object thereof is to provide a heat treatment apparatus and a heat treatment method capable of increasing an average crystal grain diameter of a silicon film to be several times as large as that of the related art, which leads to improvement of the carrier diffusion length for mainly improving characteristics of solar cells, displays and semiconductors.

In order to achieve the above object, a means to be disclosed in the present invention includes a first temperature mechanism having a heater heating a base material on the back side of the base material as well as cooling the front surface of the base material by using coolant on the front surface side of the base material, a second temperature mechanism heating the front surface side of the base material by using any of atmospheric plasma unit, laser and a flash lamp, a third temperature mechanism having a heater heating the base material from the front surface side of the base material, in which the first to third temperature mechanisms are sequentially arranged in this order, and a movement mechanism relatively moves the first to third temperature mechanisms.

It is preferable that the second temperature mechanism can realize temperature increase speed of 500° C./sec or more.

It is preferable that the means further includes a mechanism capable of moving the base material in one direction.

A means to be disclosed in the present invention includes the steps of holding a base material in at least three kinds of temperature bands which are a low-temperature band including temperatures of 600° C. or less as well as higher than 0° C., a high-temperature band including temperatures higher than 900° C. as well as lower than 1500° C. and an intermediate-temperature band including temperatures 100° C. or more lower than the high-temperature band as well as higher than the low-temperature band and switching among the three kinds of temperature bands sequentially in this order to perform heat treatment.

It is preferable that a desired material is included on the base material, and the material has a solid-phase crystallization temperature, which is the material generating crystal nuclei at least when the temperature is increased.

It is preferable that a desired material is included on the base material, and the material is silicon.

It is preferable that the high-temperature band includes temperatures higher than 1400° C. and lower than 1500° C.

It is preferable that the high-temperature band is obtained by increasing temperature by using any of an atmospheric plasma anneal method, a laser anneal method and a flash lamp anneal method.

It is preferable that switching from the low-temperature band to the high-temperature band is performed at temperature increase speed of 500° C./sec or more.

It is preferable that heat treatment is performed by switching from the low-temperature band to the high-temperature band or switching from the high-temperature band to the intermediate-temperature band by sequentially combining plural anneal methods or by combining plural heads in the same anneal method.

As described above, according to the means to be disclosed in the present invention, it is possible to provide a heat treatment apparatus and a heat treatment method capable of increasing the average crystal grain diameter of the silicon film to be several times as large as that of related art, which leads to improvement of a carrier diffusion length for mainly improving characteristics of solar cells, displays and semiconductors.

### BRIEF DESCRIPTION OF THE DRAWINGS

FIG. 1 is a schematic view showing a structure of a heat treatment apparatus according to Embodiment 1 of the present invention;

FIG. 2 is a schematic view showing a thermal profile on the front surface of a base material in a heat treatment method according to Embodiment 1 of the present invention;

FIG. 3 is a schematic view showing a structure of a heat treatment apparatus according to Embodiment 2 of the present invention;

FIG. 4 is a schematic view showing a thermal profile on the front surface of a base material in a heat treatment method according to Embodiment 2 of the present invention;

FIG. 5 is a schematic view showing a structure of a heat treatment apparatus according to Embodiment 3 of the present invention; and

FIG. 6 is a schematic view showing a structure of a heat treatment apparatus according to Embodiment 4 of the present invention.

### DESCRIPTION OF THE PREFERRED EMBODIMENTS

Hereinafter, embodiments of the present invention will be explained with reference to the drawings.

### Embodiment 1

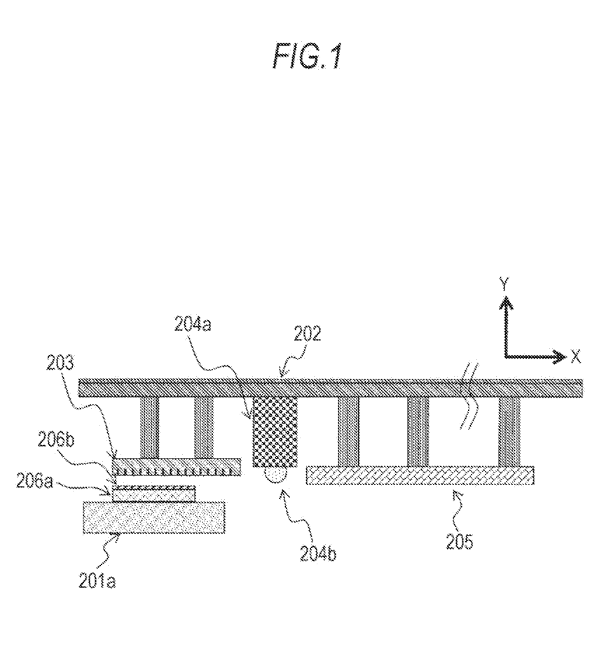

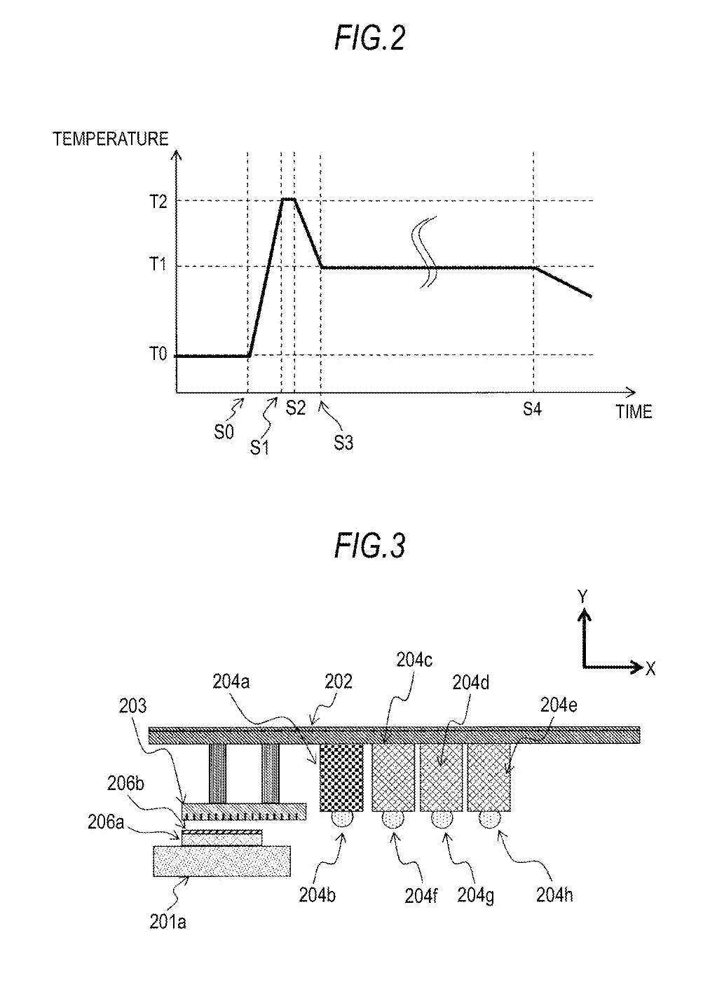

FIG. 1 and FIG. 2 are schematic views showing a heat treatment apparatus and a heat treatment method according to Embodiment 1.

### (Structure of Heat Treatment Apparatus and Method Thereof)

The heat treatment apparatus and the method thereof according to the present embodiment include a lower heater unit 201a capable of heating a base material, a carrier unit 202 capable of moving in an X direction, a gas ejection unit 203 connected to the carrier unit 202 as a cooling unit, an atmospheric plasma unit 204a as a rapid heating unit and an upper heater unit 205 as an auxiliary heating unit as shown in FIG. 1.

The treatment apparatus according to the present invention sequentially arranges the upper heater units 205 in the X direction and can switch respective temperature bands continuously and rapidly by the carrier unit while performing heat treatment in several kinds of temperature bands.

When the carrier unit 202 is moved in an -X direction, respective units of the gas ejection unit 203, the atmospheric plasma unit 204a and the upper heater unit 205 can be moved to positions facing the lower heater unit 201a through a base material 206.

Hereinafter, an example of the heat treatment method performed by using the heat treatment apparatus will be shown with reference to the schematic view of a thermal profile on the front surface of the base material 206 shown in FIG. 2. First, the base material 206 with an amorphous silicon thin film 206b having an amorphous phase being deposited on the front surface side of a glass 206a was placed on the lower heater unit 201a heated to approximately 600° C. to 800° C., and nitrogen gas was ejected to the front surface side of the base material 206 by the gas ejection unit 203 at the same time to thereby hold the front surface of the base material 206 at an relatively low temperature T0 of approximately 580° C.

Next, respective units were moved in the −X direction by the carrier unit 202 at speed of approximately 10 to 5000 mm/sec. Accordingly, the temperature on the front surface of the base material 206 was increased to approximately 1050° C. extremely rapidly in a short period of time of approximately 0.2 to 1000 msec (S0 to S1) by using a high-temperature plasma 204b ejected from the atmospheric plasma unit 204a. The front surface of the base material 206 was held at the reached temperature for approximately 0.2 to 100 msec (S1 to S2), thereby performing heat treatment of a relatively high temperature T2.

Furthermore, respective units were continuously moved by the carrier unit 202, thereby allowing the front surface of the base material 206 to be a relatively intermediate temperature T1 which was approximately 250° C. lower than the reached temperature for a short period of time of approximately 0.1 to 1000 msec (S2 to S3) by the upper heater unit 205 arranged adjacent to the atmospheric plasma unit 204a. Then, the front surface of the base material 206 was held at the intermediate temperature T1 for approximately 0.1 to 5 sec (S3 to S4), thereby performing heat treatment to the front surface of the base material 206, namely, the amorphous silicon thin film 206b in the order of the low temperature T0, the high temperature T2 and the intermediate temperature T1.

As a result of analyzing the amorphous silicon thin film 206b crystallized (phase transition was performed from the amorphous phase to a crystal phase) by the heat treatment apparatus and the method thereof as described above by TEM observation and so on, it was possible to confirm crystallization with a grain diameter approximately 6.0 times larger than related art examples in average (15 μm level). Additionally, it was also possible to confirm that no damage such as peeling or cracks on the film occurs on the glass and the silicon film used as the base material.

### Embodiment 2

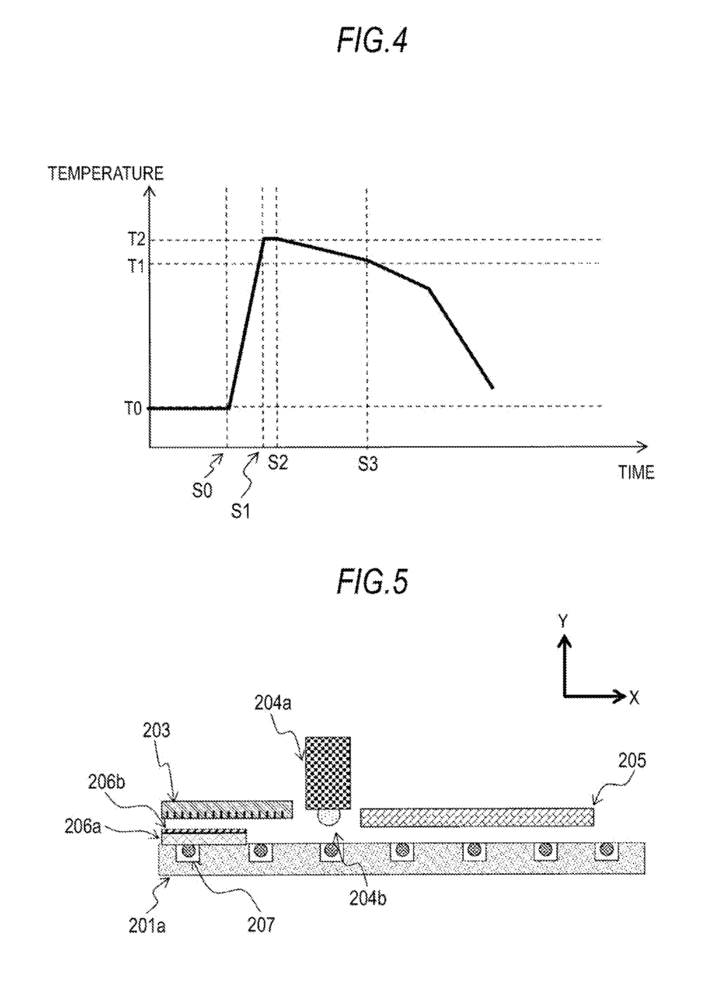

FIG. 3 and FIG. 4 are schematic views showing a heat treatment apparatus and a heat treatment method according to Embodiment 2 of the present invention. Hereinafter, points different from Embodiment 1 will be mainly described.

### (Structure of Heat Treatment Apparatus and Method Thereof)

The heat treatment apparatus and the method thereof according to the present embodiment apply a heat treatment apparatus in which atmospheric plasma units 204c, 204d and 204e as auxiliary heating units are sequentially arranged along the X direction instead of the upper heater unit 205 as the auxiliary heating unit as shown in FIG. 3.

Hereinafter, an example of the heat treatment method performed by using the heat treatment apparatus will be shown with reference to the schematic view of a thermal profile of the front surface of the base material 206 shown in FIG. 4.

First, the base material 206 with the amorphous silicon thin film 206b having the amorphous phase being deposited on the front surface side of the glass 206a was placed on the lower heater unit 201a heated to approximately 600° C. to 800° C. Nitrogen gas was ejected to the front surface side of the base material 206 by the gas ejection unit 203 at the same time to thereby hold the front surface of the base material 206 at the relatively low temperature TO of approximately 580° C.

Next, respective units were moved in the −X direction by the carrier unit 202 at speed of approximately 10 to 5000 mm/sec, thereby increasing temperature on the front surface of the base material 206 to approximately 1050° C. extremely rapidly in a short period of time of approximately 0.2 to 1000 msec (S0 to S1) by using the high-temperature plasma 204b ejected from the atmospheric plasma unit 204a. The front surface of the base material 206 was held at the reached temperature for approximately 0.2 to 100 msec (S1 to S2), thereby performing heat treatment of the relatively high temperature T2.

Furthermore, respective units were continuously moved by the carrier unit 202, high-temperature plasmas 204f, 204g and 204h were ejected by the atmospheric plasma units 204c, 204d and 204e arranged adjacent to the atmospheric plasma unit 204a, and the front surface temperature of the base material 206 is gradually decreased for a short period of time of approximately 0.6 to 3000 msec (S2 to S3) to be the relatively intermediate temperature T1 which is approximately 100° C. to 250° C. lower than the high temperature T2, then, the base material 206 was cooled naturally.

That is, heat treatment was performed to the front surface of the base material 206, namely, the amorphous silicon thin film 206b in the order of the low temperature T0, the high temperature T2 and the intermediate temperature T1 in the same manner as Embodiment 1.

At this time, power applied to the atmospheric plasma units 204c, 204d and 204e was set to be lower than power applied to the atmospheric plasma unit 204a. Specifically, when the power applied to the atmospheric plasma unit 204a was set to 1.0, the power to the atmospheric plasma units 204c, 204d and 204e was respectively set to 0.9, 0.8 and 0.7, and the high-temperature plasmas 204f, 204g and 204h which were lower in temperature than the high-temperature plasma 204b were ejected.

As a result of analyzing the silicon thin film crystallized (phase transition was performed from the amorphous phase to the crystal phase) by the heat treatment apparatus and the method thereof as described above by the TEM observation, it was possible to confirm crystallization with a grain diameter approximately 8.0 times larger than related art examples in average (20 μm level), though variation in grain size is larger than in Embodiment 1.

Additionally, it was also possible to confirm that no damage such as peeling or cracks on the film occurs on the glass and the silicon film used as the base material.

### Embodiment 3

FIG. 2 and FIG. 5 are schematic views showing a heat treatment apparatus and a heat treatment method according to Embodiment 3 of the present invention. Hereinafter, points different from Embodiment 1 will be mainly described.

### (Structure of Heat Treatment Apparatus and Method Thereof)

The heat treatment apparatus and the method thereof according to the present embodiment apply a heat treatment apparatus in which carrier rollers 207 made of ceramic capable of moving the base material 206 in the +X direction are arranged instead of the carrier unit 202 capable of moving in the X direction as shown in FIG. 5.

The same heat treatment method as Embodiment 1 was performed by using the heat treatment apparatus, thereby performing the thermal profile equivalent to the thermal profile shown in FIG. 2 on the front surface of the base material 206.

First, the base material 206 with the amorphous silicon thin film 206b having the amorphous phase being deposited on the front surface side of the glass 206a was placed on the lower heater unit 201a heated to approximately 600° C. to 800° C. Nitrogen gas was ejected to the front surface side of the base material 206 by the gas ejection unit 203 at the same time to thereby hold the front surface of the base material 206 at the relatively low temperature T0 of approximately 580° C. or less.

Next, the temperature on the front surface of the base material 206 was increased to approximately 1050° C. extremely rapidly in a short period of time of approximately 1.0 to 1000 msec (S0 to S1) by using the high-temperature plasma 204b ejected from the atmospheric plasma unit 204a in the same manner as Embodiment 1. The front surface of the base material 206 was held at the reached temperature for approximately 0.2 to 100 msec (S1 to S2), thereby performing heat treatment of the relatively high temperature T2.

Furthermore, the front surface of the base material 206 was allowed to be the relatively intermediate temperature T1 which was approximately 250 to 300° C. lower than the reached temperature for a short time of approximately 0.1 to 1000 msec (S2 to S3) by the upper heater unit 205 arranged adjacent to the atmospheric plasma unit 204a in the same manner as in Embodiment 1. Then, the front surface of the base material 206 was held at the intermediate temperature T1 for approximately 0.1 to 5 sec (S3 to S4), thereby performing heat treatment to the front surface of the base material 206, namely, the amorphous silicon thin film 206b in the order of the low temperature T0, the high temperature T2 and the intermediate temperature T1.

A point different from Embodiment 1 in the heat treatment method is that the base material 206 was moved in the +X direction by the carrier rollers 207 at speed of approximately 10 to 1000 mm/sec.

As a result of analyzing the silicon thin film crystallized (phase transition was performed from the amorphous phase to the crystal phase) by the heat treatment apparatus and the method thereof as described above by TEM observation and so on, it was possible to confirm crystallization with a grain diameter approximately 5.0 times larger than related art examples in average (12.5 μm level), though variation in grain size is larger than in Embodiment 1.

Additionally, it was also possible to confirm that no damage such as peeling or cracks on the film occurs on the glass and the silicon film used as the base material.

### Embodiment 4

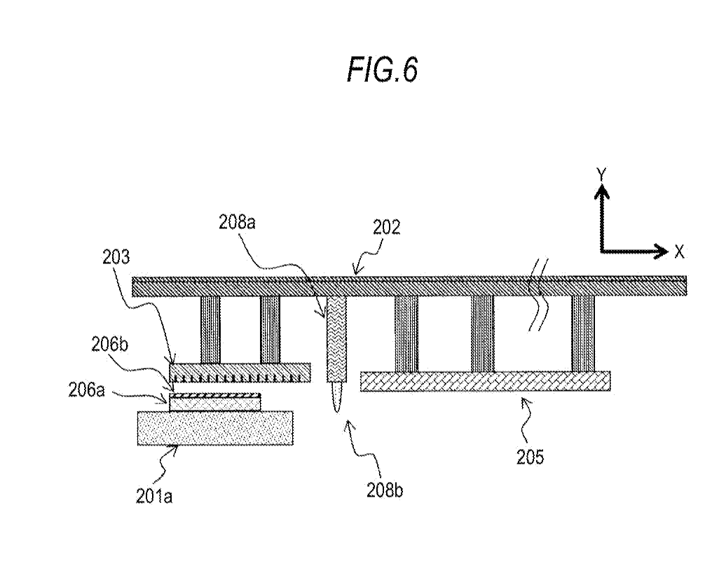

FIG. 6 and FIG. 2 are schematic views showing a heat treatment apparatus and a heat treatment method according to Embodiment 4 of the present invention. Hereinafter, points different from Embodiment 1 will be mainly described.

### (Structure of Heat Treatment Apparatus and Method Thereof)

The heat treatment apparatus and the method thereof according to the present embodiment apply a heat treatment apparatus in which a laser unit 208a using green laser of a wavelength 530nm is arranged instead of the atmospheric plasma unit 204a as the rapid heating unit as shown in FIG. 6.

The same heat treatment method as Embodiment 1 was performed by using the heat treatment apparatus, thereby performing the thermal profile equivalent to the thermal profile shown in FIG. 2 on the front surface of the base material 206.

First, the base material 206 with the amorphous silicon thin film 206b having the amorphous phase being deposited on the front surface side of the glass 206a was placed on the lower heater unit 201a heated to approximately 600° C. to 800° C. Nitrogen gas was ejected to the front surface side of the base material 206 by the gas ejection unit 203 at the same time to thereby hold the front surface of the base material 206 at the relatively low temperature T0 of approximately 580° C. or less.

Next, a point different from Embodiment 1 in the heat treatment method is that the temperature on the front surface of the base material 206 was increased to approximately 1300° C. extremely rapidly in a short period of time of approximately 0.1 to 500 msec (S0 to S1) by using a laser 208b ejected from the laser unit 208a. The front surface of the base material 206 was held at the reached temperature for approximately 0.1 to 500 msec (S1 to S2), thereby performing heat treatment of the relatively high temperature T2.

Furthermore, the front surface of the base material 206 was allowed to be the relatively intermediate temperature T1 which was approximately 500° C. lower than the reached temperature for a short time of approximately 0.1 to 1000 msec (S2 to S3) by the upper heater unit 205 arranged adjacent to the laser unit 208a in the same manner as in Embodiment 1. Then, the front surface of the base material 206 is held at the intermediate temperature T1 for approximately 0.1 to 5 sec (S3 to S4), thereby performing heat treatment to the front surface of the base material 206, namely, the amorphous silicon thin film 206b in the order of the low temperature T0, the high temperature T2 and the intermediate temperature T1.

As a result of analyzing the silicon thin film crystallized (phase transition was performed from the amorphous phase to the crystal phase) by the heat treatment apparatus and the method thereof as described above by TEM observation and so on, it was possible to confirm crystallization with a grain diameter approximately 4.5 times larger than related art examples in average (1.25 μm level), though the area in which crystallization was performed is smaller than in Embodiment 1.

Additionally, it was also possible to confirm that no damage such as peeling or cracks on the film occurs on the glass and the silicon film used as the base material.

The estimation for the reasons that the crystallization can be performed with a larger grain diameter than related art examples as described above will be described below.

As in related art examples, the amorphous silicon film forms microcrystal grains of approximately Φ10 nm uniformly in the entire film when performing heat treatment at approximately the vicinity of 625° C. for several seconds to several minutes. Accordingly, heat treatment is further continued in units of several to several dozen hours by using the SPC method utilizing the solid state properties, thereby forming crystal grains in the Φ2.5 μm level at the maximum. However, even when heat treatment is performed for more than the above hours, the crystal grains is hardly increased.

This is because, when extremely fine crystal grains having the size of Φ10 nm or less are formed in high density at the early stage of heat treatment, the grain boundary area may be drastically increased as well as respective grains may be oriented at random. As a result, it is presumable that enormous thermal energy will be necessary for grain growth (expansion of the grain diameter), and the grain growth to more than a certain size becomes difficult.

In response to the above, there are three main features in the present embodiment as compared with related art examples. The features will be shown by citing the silicon film on glass used in the present embodiment as an example of a desired material.

The first feature is to heat the silicon film rapidly to more than a temperature of phase transformation of the silicon film. In order to realize the feature, the embodiments of the present invention apply the configuration in which the temperature of auxiliary heating is suppressed to a temperature lower than the vicinity of 625° C. as a temperature at which nuclei start to be generated in the silicon film while giving auxiliary heating to the silicon film for assisting the heating to the reached temperature, and further, the configuration in which the silicon film is rapidly heated in the order of msec continued from a low temperature band.

According to the heat treatment apparatus and the heat treatment method having the above configurations, the temperature of the silicon film in the state of the amorphous phase can be increased rapidly to a temperature more than the vicinity of 900° C. as the temperature at which phase transformation from the amorphous phase to the crystal phase starts to occur while passing through the temperature band of the vicinity of 625° C. at a moment. As a result, it is presumable that the frequency of generation of nuclei at the temperature up as the characteristic of the silicon film can be suppressed as low as possible.

The second feature is in the configuration of heat treatment apparatus and the method thereof in which the base material is constantly heated by the lower heater and so on. After the atmospheric plasma unit, the laser unit or the like allowing the silicon film to reach a high temperature band passes by, the silicon film is immediately held in an intermediate temperature band 100° C. to 500° C. lower than the high temperature band. As a result, it is presumable that a supercooling degree of the silicon film can be suppressed to be relatively small as well as the frequency of generation of nuclei at the temperature down can be suppressed.

According to the above features, it can be considered that the frequency of generation of crystal nuclei in the silicon film can be suppressed to be low both at the temperature up and temperature down, and that the crystal grain diameter larger than related art examples can be realized.

Lastly, the third feature is to use the ultra-rapid heating technique such as the atmospheric plasma, laser and flash lamp anneal for the high temperature band. According to the technique, the heat diffusion length into the glass can be suppressed to the several dozen μm level, and glass can be used without damage such as warpage or cracks. As a result, the present invention can be easily used for the fields of solar cells, displays and semiconductors.

According to the above reasons, when films other than the silicon film are targeted, the temperature of microcrystallization or the temperature of nuclei generation or less which is peculiar to the film is determined to be the low-temperature band.

In the case where the amorphous silicon film is targeted as in the present embodiment, the low-temperature band preferably includes temperatures lower than 600° C. as well as higher than 0° C. This is because the temperature at which crystal nuclei of silicon are generated (generally called a microcrystallization temperature) is approximately 625° C., and temperatures lower than 600° C. are preferable for suppressing the generation of crystal nuclei. On the other hand, temperatures lower than 0° are not preferable as moisture in the air tends to be condensed on the film surface, which may cause variations in desired effects.

It is further preferable that the low-temperature band includes temperatures higher than 500° C. as the intermediate temperature can be immediately maintained after the processing in the high-temperature band.

In the case where the amorphous silicon film is targeted as in the present embodiment, the reached temperature of the high-temperature band is preferably higher than 900° C. as well as lower than 1500° C. This is because, as the temperature at which phase transformation from the amorphous phase to the crystal phase of silicon starts to occur is in the vicinity of 900° C., or as a melting temperature of silicon is in the vicinity of 1414° C., the crystal phase with a larger crystal grain diameter can be easily obtained by increasing temperature to any of these temperature bands.

In the case where the amorphous silicon film on glass is targeted as in the present embodiment, the intermediate-temperature band preferably includes temperatures 100° C. lower than the high-temperature band as well as higher than the low-temperature band.

As crystal nuclei can be generated by maintaining the temperature in the temperature band lower than the high-temperature band, it is preferable to maintain the temperature approximately at 100° C. lower than the high-temperature band. On the other hand, in order to suppress the frequency of generation of crystal nuclei to be relatively low, a means of reducing the supercooling degree is effective.

It is also preferable to maintain the temperature to temperatures approximately higher than the low-temperature band in order to obtain sufficient diffusion speed of silicon and to increase grain growth speed of crystal grains. It is further preferable the intermediate-temperature band includes temperatures of 800° C. or less for avoiding damage on glass such as warpage, cracks and so on.

Though the case where the gas ejection unit is used as the cooling unit has been cited in the above embodiments, it is possible to perform heating to be in the low-temperature band even when a unit capable of ejecting liquid-state coolant such as water instead of the gas ejection unit.

Though the cases where the atmospheric plasma unit and the laser unit are used as rapid heating units have been cited in the present embodiments, other heating means can be used as long as the temperature can be rapidly increased to the high temperature. For example, the front surface of the base material can be rapidly heated even when a flash lamp annealing unit is used instead of the above units, by performing heating so as to be synchronized with positional relation with respect to the base material.

Though the case where the lower and upper heaters are used and the case where the lower heater and plural atmospheric plasma units with suppressed outputs are used as heat treatment means for the intermediate-temperature band have been cited in the present embodiments, other heating means can be used. For example, it is possible to rapidly perform heating the front surface of the base material to be in the intermediate-temperature band even when plural laser units, plural flash lamp annealing units and so on are used instead of the atmospheric plasma units.

Though only the silicon film on glass as the base material has been cited in the present embodiments, it is possible to apply a case where a material having higher thermal conductivity than glass is sandwiched between the glass and the silicon film to be a stacked structure including the silicon film/high-thermal conductivity film/glass.

In the heat treatment apparatus and the heat treatment method according to the present invention, the average crystal grain diameter of the silicon film can be increased more than 4.5 times as large as that of related art and the carrier diffusion length can be improved, which can mainly improve characteristics of solar cells, displays and semiconductors.

What is claimed is:

1. A heat treatment apparatus comprising:
a first temperature mechanism including a heater configured to heat to a back side of a base material as well as cool a front surface of the base material by using coolant on the front surface of the base material;
a second temperature mechanism configured to heat the front surface of the base material by using any of atmospheric plasma unit, laser and a flash lamp;
a third temperature mechanism including a heater configured to heat the base material from the front surface of the base material,
wherein the first to third temperature mechanisms are sequentially arranged in this order; and
a movement mechanism configured to relatively move the first to third temperature mechanisms.

2. The heat treatment apparatus according to claim 1,
wherein the second temperature mechanism is configured to increase of the base material temperature at a speed of 500° C./sec or more.

3. The heat treatment apparatus according to claim 1, further comprising:
a mechanism configured to move the base material in one direction.

4. A heat treatment method comprising:
holding a base material in at least three kinds of temperature bands including a low-temperature band of temperatures of 600° C. or less and higher than 0° C., a high-temperature band of temperatures higher than 900° C. and lower than 1500° C. and an intermediate-temperature band of temperatures 100° C. or more lower than the high-temperature band and higher than the low-temperature band; and
switching among the three kinds of temperature bands sequentially in this order to perform heat treatment.

5. The heat treatment method according to claim 4,
wherein a predetermined material is included on the base material,
the predetermined material has a solid-phase crystallization temperature, and generates crystal nuclei at least when the temperature of the predetermined material is increased beyond the solid-phase crystallization temperature.

6. The heat treatment method according to claim 4,
wherein silicon is included on the base material.

7. The heat treatment method according to claim 4,
wherein the high-temperature band includes temperatures higher than 1400° C. and lower than 1500° C.

8. The heat treatment method according to claim 4,
wherein the high-temperature band is obtained by increasing temperature by using any of an atmospheric plasma anneal method, a laser anneal method and a flash lamp anneal method.

9. The heat treatment method according to claim 4,
wherein switching from the low-temperature band to the high-temperature band is performed at temperature increase speed of 500° C./sec or more.

10. The heat treatment method according to claim 4,
wherein heat treatment is performed by switching from the low-temperature band to the high-temperature band or switching from the high-temperature band to the intermediate-temperature band by sequentially combining plural anneal methods or by combining plural heads in the same anneal method.
